(19) United States
(12) Patent Application Publication
(10) Pub. No.: US 2026/0361072 A1
(43) Pub. Date: Nov. 12, 2026

(54) ELECTRONIC FUSE CONTROLLER WITH MODULATED OUTPUT CURRENT FOR ELECTRO-IMPEDANCE SPECTROSCOPY EXCITATION

(71) Applicant: Analog Devices International Unlimited Corporation, Limerick (IE)

(72) Inventor: Uwe Broeckelmann, Issing (DE)

(21) Appl. No.: 19/204,686

(22) Filed: May 12, 2025

(51) Int. Cl. H02H 7/18; G01R 31/389; H02H 1/00; H02H 9/02; H02J 7/62

(52) U.S. Cl. CPC H02H 7/18; G01R 31/389; H02H 1/0007; H02H 9/025; H02J 7/62

(57) ABSTRACT

A primary control unit operates in a first operating mode to protect at least one switching element from experiencing an overcurrent event. The primary control unit operates in a second operating mode to generate one or more stimulus signals to drive the at least one switching element. In the second operating mode, the primary control unit causes one or more response signals to be captured in response to the one or more stimulus signals. The one or more response signals are one or more impedance measurements associated with a battery. The one or more impedance measurements may be compared to known signatures of impedance responses of other batteries with known characteristics to identify the characteristics of the battery being stimulated. As a result of determining the characteristics of the battery being simulated, charging or discharging operations may be tailored to the particular characteristics of the battery.

### BACKGROUND

### Technical Field

Embodiments described herein relate to circuitry, and more particularly, to techniques for efficiently managing power distribution.

### Description of the Related Art

Protection devices can be used for protecting electrical components in electronic systems. Traditionally, mechanical fuses have been used as electrical safety devices to provide protection for downstream circuitry against overcurrent events in electrical circuits. In a mechanical fuse, in the event of an overcurrent event such as a short circuit or overload, a metal wire or metal strip within the fuse device melts and current flowing in the circuit is interrupted. In this manner, an electrical component is not subjected to excess current over a period of time that could cause the electrical component to be irreversibly damaged. Depending upon the specific application, a mechanical fuse can be designed to accommodate specific current and voltage ratings, breaking capacity, and response time. However, mechanical fuses are sacrificial circuit elements and, once an overcurrent event occurs, must be replaced.

### SUMMARY

Various embodiments of systems, apparatuses, and methods for efficient power management and distribution techniques are contemplated.

In one embodiment, a primary control unit operates in a first operating mode to prevent an excessive amount of current passing through at least one switching element. In this embodiment, the primary control unit operates in a second operating mode to generate one or more stimulus signals to drive the at least one switching element. In the second operating mode, the primary control unit may cause one or more response signals to be captured in response to the one or more stimulus signals. The primary control unit may also cause the capturing of the one or more response signals to be synchronized with the generation of the one or more stimulus signals. In one embodiment, the one or more response signals are one or more impedance measurements associated with a battery. The one or more impedance measurements may be compared to known signatures of impedance responses to identify the characteristics of the battery being stimulated. As a result of determining the characteristics of the battery being simulated, charging or discharging operations may be tailored to the particular characteristics of the battery. Other advantages may also be attained by determining the characteristics of the battery.

These and other embodiments will become apparent upon consideration of the following description and accompanying drawings.

### BRIEF DESCRIPTION OF THE DRAWINGS

FIG. 1 is a diagram illustrating one embodiment of a system, according to an embodiment of the present disclosure.

FIG. 2 illustrates a diagram of one embodiment of an apparatus, according to an embodiment of the present disclosure.

FIG. 3 is a diagram illustrating one embodiment of a system for combining stimulus excitation with circuit breaking functionality, according to an embodiment of the present disclosure.

FIG. 4 illustrates a diagram of one embodiment of an apparatus for combining electronic fuse functionality with electro-impedance spectroscopy stimulus functionality, according to an embodiment of the present disclosure.

FIG. 5 illustrates a diagram of one embodiment of a system, according to an embodiment of the present disclosure.

FIG. 6 is a generalized flow diagram illustrating one embodiment of a method for employing current clamping via external compensation, according to an embodiment of the present disclosure.

FIG. 7 is a generalized flow diagram illustrating one embodiment of a method for employing software control of current clamping via external compensation, according to an embodiment of the present disclosure.

FIG. 8 is a generalized flow diagram illustrating one embodiment of a method for employing software control of current clamping via external compensation, according to an embodiment of the present disclosure.

FIG. 9 is a block diagram illustrating an example of a machine upon which one or more embodiments may be implemented, according to an embodiment of the present disclosure.

While the methods and mechanisms described herein are susceptible to various modifications and alternative forms, specific embodiments are shown by way of example in the drawings and are herein described in detail. It should be understood, however, that drawings and detailed description thereto are not intended to limit the methods and mechanisms to the particular form disclosed, but on the contrary, are intended to cover all modifications, equivalents and alternatives apparent to those skilled in the art once the disclosure is fully appreciated.

### DETAILED DESCRIPTION

In the following description, numerous specific details are set forth to provide a thorough understanding of the methods and mechanisms presented herein. However, one having ordinary skill in the art should recognize that the various embodiments may be practiced without these specific details. In some instances, well-known structures, components, signals, computer program instructions, and techniques have not been shown in detail to avoid obscuring the approaches described herein. It will be appreciated that for simplicity and clarity of illustration, elements shown in the figures have not necessarily been drawn to scale. For example, the dimensions of some of the elements may be exaggerated relative to other elements.

This specification includes references to “one embodiment”. The appearance of the phrase “in one embodiment” or the phrase “in an embodiment” in different contexts does not necessarily refer to the same embodiment. Particular features, structures, or characteristics may be combined in any suitable manner consistent with this disclosure. Furthermore, as used throughout this application, the word “may” is used in a permissive sense (i.e., meaning having the potential to), rather than the mandatory sense (i.e., meaning must). Similarly, the words “include”, “including”, and “includes” mean including, but not limited to.

Terminology. The following paragraphs provide definitions and/or context for terms found in this disclosure (including the appended claims): “Comprising.” This term is open-ended. As used in the appended claims, this term does not foreclose additional structure or steps. Consider a claim that recites: “A system comprising an amplifier . . . .” Such a claim does not foreclose the system from including additional components (e.g., a capacitor, a resistor, a central processing unit).

“Configured To.” Various units, circuits, or other components may be described or claimed as “configured to” perform a task or tasks. In such contexts, “configured to” is used to connote structure by indicating that the units/circuits/components include structure (e.g., circuitry) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. § 112, paragraph (f), for that unit/circuit/component. Additionally, “configured to” can include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

Generally, electrochemical impedance spectroscopy or electro-impedance spectroscopy (EIS) is a technique for characterizing electrochemical devices and systems (e.g., electrochemical cells). Often, this technique involves the measurement of electrochemical impedance of a device (e.g., a battery cell) or system over a range of frequencies. Usually, properties of the device or system may be ascertained from this measurement. These properties include, but are not limited to, energy storage and dissipation characteristics.

Generally, electrochemical impedance may be measured by applying an alternating current (AC) signal, such as a sinusoidal test voltage or current, to an electrochemical cell under test and then measuring the current through the electrochemical cell. Typically, EIS uses measurement of impedance over a suitable frequency range. Often, this can provide a useful technique to investigate the electrical properties of a large variety of materials and devices such as batteries.

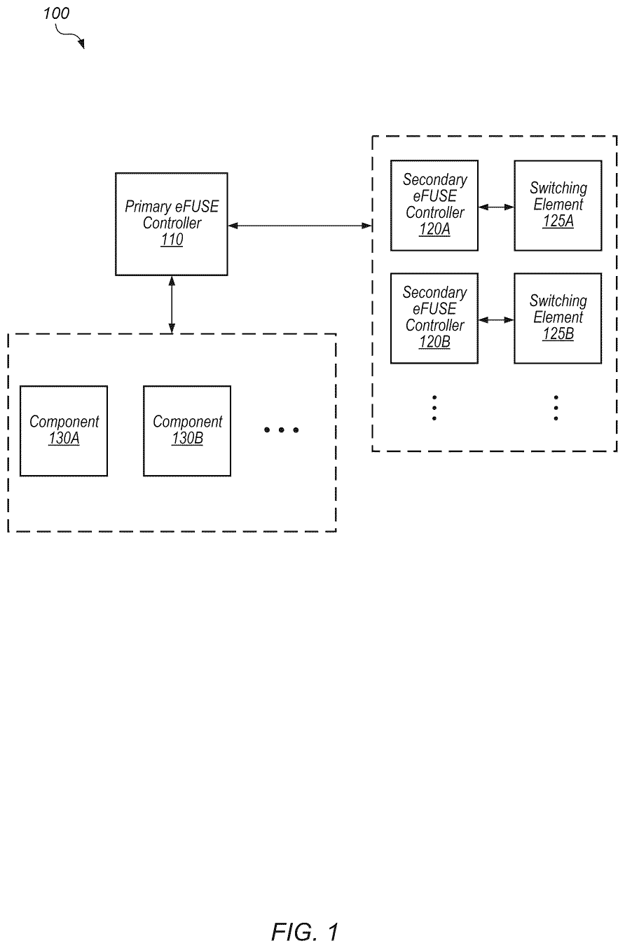

Referring now to FIG. 1, a block diagram of a system 100 is shown, in accordance with one or more embodiments. In an embodiment, system 100 includes at least a primary electronic fuse (eFUSE) controller 110, secondary eFUSE controllers 120A-120B, switching elements 125A-125B, and components 130A-130B. Components 130A-130B are representative of any number and type of components, such as direct current (DC)-DC converter, battery management system (BMS), battery packs, battery modules, fuel cells, solar panels, loads, and so on. Switching elements 125A-B are representative of any number and type of switching elements, such as eFUSEs, circuit breakers, switching modules, and so on.

Primary eFUSE controller 110 may be implemented using any suitable combination of hardware (e.g., processing units, microprocessors, digital signal processors (DSPs), central processing units (CPUs), field-programmable gate arrays (FPGAs), application-specific integrated circuits (ASICs)) and/or software (e.g., program instructions). The hardware to implement primary eFUSE controller 110 may include circuitry, physical circuit elements, processing units, programmable logic gates, and so on. The software to implement primary eFUSE controller 110 may include program instructions, code, firmware, microcode, and so on. The program instructions may be stored on one or more computer-readable storage media (i.e., one or more memory devices). It is noted that primary eFUSE controller 110 may also be referred to herein as a “primary control unit”. It is also noted that secondary eFUSE controllers 120A-120B may also be referred to herein as “secondary control units”.

In an embodiment, primary eFUSE controller 110 is configured to operate in a plurality of operating modes, with each operating mode corresponding to a different set of functionality to be implemented and/or different sets of functions to be performed. For example, in a first operating mode, primary eFUSE controller 110 is configured to operate only as a current limiting controller to prevent more than a threshold amount of current from flowing through one or more loads. In this example, in a second operating mode, primary eFUSE controller 110 is configured to generate EIS stimulus excitation current to be applied to one or more loads of system 100. During the second operating mode, eFUSE controller 110 also monitors the current flowing through various components to ensure the current does not exceed each component's maximum allowable current. If this maximum allowable current is exceeded, eFUSE controller 110 may send a control signal to the corresponding switching element 125A-125B to cause the current flowing through the respective component to be reduced and/or turned off.

During the second operating mode, primary eFUSE controller 110 is configured to synchronize the timing of EIS stimulus excitation current with the monitoring of the battery cell voltages and currents performed by one or more battery management systems. This synchronization ensures that the captured battery cell voltages and currents are matched with the timing of the EIS stimulus.

In an embodiment, primary eFUSE controller 110 generates single-tone EIS stimulus by generating a stimulus signal at a single frequency of interest which is applied to a single switching element of switching elements 125A-B. In an example, the stimulus signal may be in the form of a PWM signal. However, other types of stimulus signals besides PWM signals may be generated in other examples. Accordingly, in this specification, when a PWM signal is described as being generated, it should be understood that this does not preclude other types of stimulus signals from being generated.

In an embodiment, primary eFUSE controller 110 generates multi-tone

EIS stimulus by generating stimulus signals at multiple different frequencies which are applied to multiple switching elements of switching elements 125A-B. These multiple different frequencies may also be referred to as parallel frequencies. For example, a first stimulus signal may be generated at a first frequency, a second stimulus signal may be generated at a second frequency, a third stimulus signal may be generated at a third frequency, and so on. Generating multi-tone EIS stimulus may result in more efficient and/or faster characterization of a corresponding battery module.

In an embodiment, primary eFUSE controller 110 determines which switching elements 125A-125B to select to apply the EIS stimulus to based on status signals received from secondary eFUSE controllers 120A-120B. For example, secondary eFUSE controllers 120A-120B may send status information back to primary eFUSE controller 110 informing primary eFUSE controller 110 of the current flowing through each corresponding switching element 125A-125B. If the current flowing through a given switching element is within a suitable (i.e., preferred) range, then primary eFUSE controller 110 may select that given switching element as a suitable switching element for receiving EIS stimulus. There may be multiple switching elements to choose from, and primary eFUSE controller 110 may select the switching element that has the most favorable operating conditions. For example, if there are 12 switching elements in a given embodiment, and the primary eFUSE controller 110 will be performing single-tone EIS stimulus, then the primary eFUSE controller 110 may select the switching element out of the 12 switching elements which has the most favorable characteristics. In one embodiment, primary eFUSE controller 110 may rank the plurality of switching elements and select the switching element that has the highest ranking. The ranking may be based on a weighted formula, with various weights applied to the different status indicators associated with each switching element. A first status indicator may be an amount of headroom between real-time current consumption and a current limit, a second status indicator may measure the impact (i.e., disruption) that EIS stimulus would have on the operation of the loads connected to the switching element, and so on. Some status indicators may be deemed to be more important and hence may have a relatively higher weight applied to them as compared to less important status indicators which have a relatively lower weight applied to them.

In an embodiment, a first given component 130A is a direct current (DC)-DC converter which converts a relatively high voltage generated by a second given component 130B (e.g., a high-voltage battery) into a relatively lower voltage which is consumed by one or more loads (e.g., a third given component, a fourth given component). In this embodiment, when primary eFUSE controller 110 is in EIS stimulus mode, primary eFUSE controller 110 causes the DC-DC converter to operate in a path-through mode in order to cause the one or more generated stimulus frequencies to pass through unfiltered to the high-voltage battery. The DC-DC converter's path-through mode may be a different operating mode than the standard operating mode in which the DC-DC converter operates when EIS stimulus is not being generated. In other words, the DC-DC converter may have a first operating mode which is used for standard operating conditions when EIS stimulus is not being generated, a second operating mode (i.e., path-through mode) when EIS stimulus is being generated, and optionally one or more other operating modes. Primary eFUSE controller 110 may be configured to cause the DC-DC converter to switch between the different operating modes. In this specification, a “DC-DC converter” may be referred to more generally as a “power converter”.

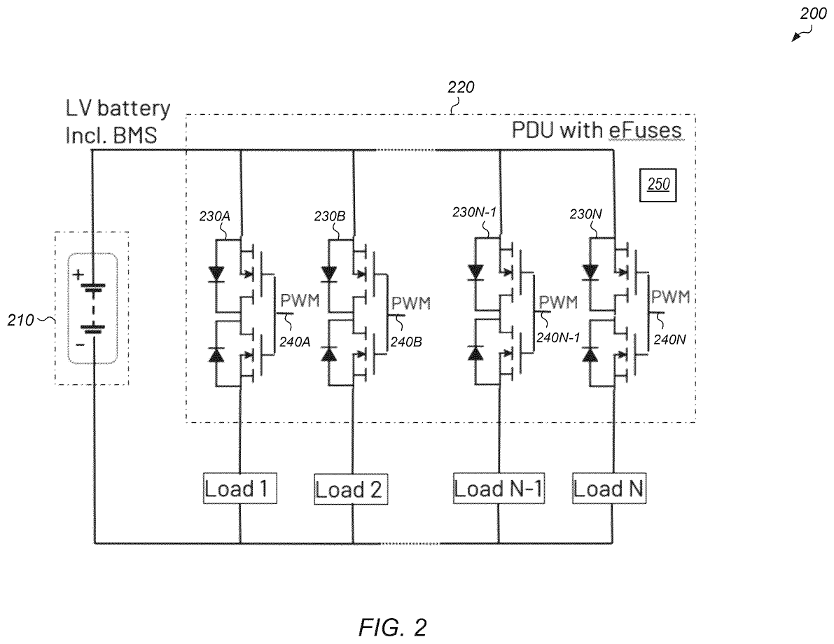

Turning now to FIG. 2, a diagram of an apparatus 200 is shown, in accordance with one or more embodiments. In one embodiment, apparatus 200 includes at least battery 210, power distribution unit 220, and a variable number “N” of loads. It is noted that apparatus 200 may include any number of other components which are not shown to avoid obscuring the figure. It is also noted that apparatus 200 may include more or fewer of the components shown in FIG. 2 in other embodiments. For example, apparatus 200 may include multiple batteries although only a single battery 210 is shown in FIG. 2. In other words, battery 210 is representative of any number of batteries. Accordingly, battery 210 may also be referred to as a “battery pack” or “battery module”. In another embodiment, apparatus 200 may be incorporated within a system which includes additional components which are not shown in FIG. 2.

In one embodiment, battery 210 may include a battery management system. Battery 210 may have any number of cells and supply any suitable voltage, with the number of cells and the voltage being supplied varying according to the embodiment. In one embodiment, battery 210 includes an analog front end, with the analog front end including a unit configured to measure and calculate the imaginary and real value of the current and the cell voltages during EIS stimulus. Depending on the embodiment, current sensing may be carried out on the low side or the high side of battery 210.

Power distribution unit 220 may control the current flowing through some number of loads, with “N” loads shown in FIG. 2, with “N” being representative of a positive integer, and with “N” varying from embodiment to embodiment. The N loads are representative of any number and type of circuits, apparatuses, modules, systems, or other elements which are consuming current generated by battery 210. For example, a first load may be a first type of circuit or component, a second load may be a second type of circuit or component, a third load may be a battery charger, and so on.

Power distribution unit 220 includes any number of switching elements 230A-N, with the number of switching elements 230A-N varying according to the embodiment. Each switching element 230A-N includes a corresponding input control port 240A-N. In one embodiment, each switching element 230A-N is an electronic fuse. As used herein, the term “electronic fuse” may be defined as a software-controlled switching device that emulates a melting fuse function by limiting the amount of current flowing through the switching device. The limiting of the amount of current flowing through the switching device may be achieved by performing one or more of: high side current detection, l2t curve emulation, and high side driver control. An electronic fuse may replace a mechanical fuse in various applications (e.g., automotive applications). It is noted that the terms “electronic fuse” and “eFUSE” may be used interchangeably herein. When a switching element 230A-N is an eFUSE, the corresponding input control port 240A-N may be referred to as an eFUSE gate. In another embodiment, each switching element 230A-N is a circuit breaker. In a further embodiment, some switching elements 230A-N are electronic fuses while other switching elements 230A-N are circuit breakers. In other embodiments, switching elements 230A-N may be any of various other types of switching components and/or devices.

Power distribution unit 220 also includes control unit 250 and during EIS stimulus, control unit 250 may add an electrical signal to the current passing through battery 210 while simultaneously taking various impedance measurements of battery 210. By comparing the impedance response of battery 210 to known signatures of impedance responses of other batteries with known characteristics, the characteristics of battery 210 may be identified. These characteristics include, but are not limited to, charge and discharge conditions, anode conditions, and cathode conditions. Based on the characteristics that are determined for battery 210, charging and discharging operations may be tailored to the particular characteristics of battery 210. For example, the charging rate of battery 210 may be adjusted based on a particular battery condition that is identified for battery 210. In another example, a protective action may be performed for battery 210 based on a particular battery condition that is identified for battery 210.

In one embodiment, control unit 250 is configured to drive input control ports 240A-N (of switching elements 230A-N) with control signals using a desired stimulus frequency. In one embodiment, control unit 250 generates a plurality of pulse-width modulation (PWM) signals, with each PWM signal of the plurality of PWM signals at a given frequency, with the given frequency varying depending on operating conditions. The control signals that are used to drive input control ports 240A-N may be synchronized across the multiple switching elements 230A-N to allow for sufficient power delivery for each load as well as sufficient stimulus current for load excitation. In some cases, single-tone excitation (with one frequency) may be implemented, while in other cases, multi-tone excitation (with two or more frequencies) may be employed. In other words, multi-tone excitation involves exciting different currents over parallel frequencies through multiple loads.

It is noted that control unit 250 may also be referred to as an eFUSE controller. In one embodiment, the eFUSE controller may be extended with the capability to drive an eFUSE gate driver with a PWM signal at a programmable stimulus frequency. In some embodiments, EIS stimulus (EISS) eFUSE controllers may be mixed with non-EISS controllers inside a power distribution unit (PDU). In one embodiment, the eFUSE controller performs a monitoring function which will stop EISS function if the load current exceeds a programmable threshold.

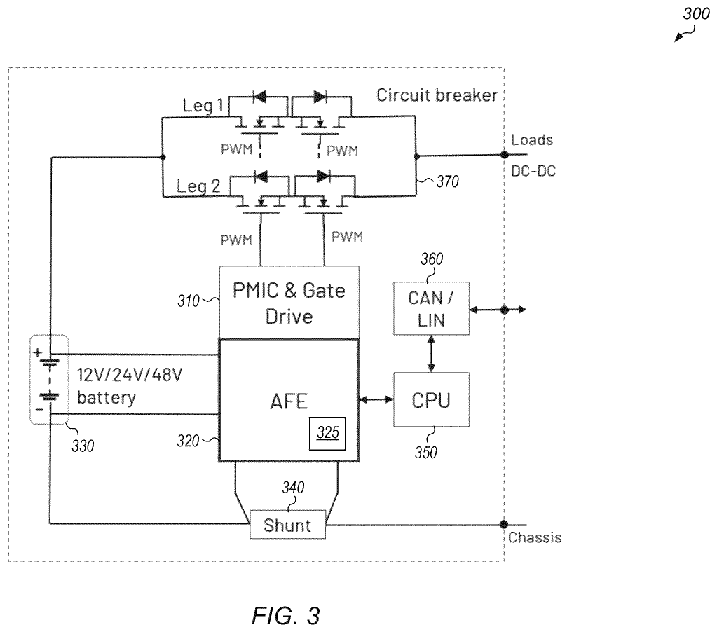

Referring now to FIG. 3, a block diagram of a system 300 for combining stimulus excitation with circuit breaking functionality is shown, in accordance with one or more embodiments. In one embodiment, system 300 includes power management integrated circuit (PMIC) and gate drive unit 310, analog front end (AFE) 320, battery 330, shunt 340, central processing unit (CPU) 350, control area network (CAN) or local interconnect network (LIN) 360, and circuit breaker 370. Circuit breaker 370 may include any number of legs supplying any number of loads, with the number of legs varying according to the embodiment. It is noted that circuit breaker 370 may be replaced with an eFUSE in other embodiments. The voltage supplied by battery 330 to system 300 may vary from embodiment to embodiment. System 300 may also include any number of other components which are not shown to avoid obscuring the figure. It is also noted that the components of system 300 may be arranged in other suitable manners different from what is shown in FIG. 3 in other embodiments.

CPU 350 may include one or more memory devices (e.g., caches) and/or be coupled to one or more memory devices (e.g., non-transitory computer readable storage medium) for storing program instructions. The program instructions may be executable by CPU 350 to cause CPU 350 to perform one or more functions as described herein. CPU 350 may send control signals to AFE 320, and CPU 350 may receive status information from AFE 320. In one embodiment, CPU 350 sends control signals to PMIC 310 and AFE 320 and to cause PMIC 310 and AFE 320 to transition between different operating modes. For example, AFE 320 may operate in a first operating mode as an eFUSE controller and AFE 320 may operate in a second operating mode as an EIS controller. Other types of operating modes are possible and are contemplated. For example, PMIC 310 and AFE 320 may also operate in different sub-operating modes to generate different types of EIS stimulus patterns and/or frequencies when operating in the second operating mode as an EIS controller.

AFE 320 includes control unit 325, with control unit 325 configured to measure and calculate the imaginary and real values of the current and cell voltages of battery 330. The imaginary and real values of the current may be referred to as the “complex current”, and the imaginary and real values of the voltage may be referred to as the “complex voltage”. Current sensing may be performed on the low side or the high side of the battery 330. In one embodiment, control unit 325 may generate stimulus EIS frequency inside AFE 320 and drive gate drive control pins for circuit breaker 370 with a PWM signal using the desired stimulus frequency. The PWM drive may be carried out at only one switching element or at multiple switching elements depending on the needed excitation current.

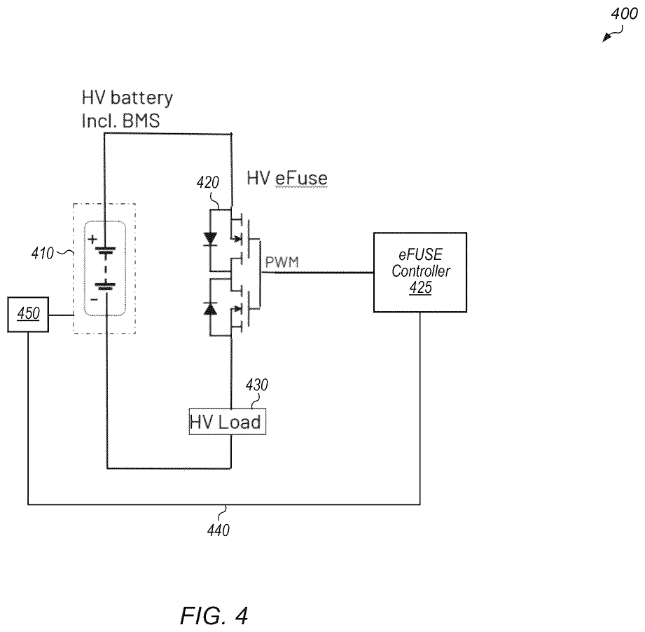

Turning now to FIG. 4, a block diagram of one embodiment of an apparatus 400 for combining eFUSE functionality with EIS stimulus functionality is shown, in accordance with one or more embodiments. In an embodiment, apparatus 400 includes battery 410, switching element 420, high-voltage (HV) load 430, bus 440, and cell monitor 450. It is noted that apparatus 400 may also include any number of other components which are not shown to avoid obscuring the figure.

In an embodiment, apparatus 400 is part of a vehicle. In an embodiment, the vehicle is an electrified vehicle (e.g., an electric automobile). In such an embodiment, HV load 430 may be a heating ventilation air conditioning (HVAC) system, although in other embodiments, HV load 430 may represent other types of loads besides a HVAC system. For example, in another embodiment, an active suspension system may be another type of HV load 430. In one embodiment, switching element 420 is a high voltage (HV) eFUSE. eFUSE 420 may be built using a silicon carbide metal-oxide semiconductor field-effect transistor (SI-MOSFET), a junction field-effect transistor (JFET), or any other suitable type of transistor. However, in other embodiments, switching element 420 may be constructed using other types of switching components.

In an embodiment, eFUSE controller 425 controls the generation of signals which are driven to the gate of switching element 420 to perform at least two different functions. A first function involves operating switching element 420 as if switching element 420 were an electronic fuse to prevent over-current events. For the first function, eFUSE controller 425 protects against overcurrent through switching element 420 by opening a current path of switching element 420 when an overcurrent event is detected. A second function performed by eFUSE controller 425 involves implementing EIS excitation of battery 410 by driving EIS excitation signals to the gate of switching element 420. For the second function, in one embodiment, eFUSE controller 425 receives an indication of the current flowing through HV load 430, and if the current flowing through HV load 430 is less than a programmable threshold, then eFUSE controller 425 drives EIS excitation signals to the gate of switching element 420. eFUSE controller 425 may also receive additional status information, such as the status (e.g., temperature) of the cells within battery 410 as well as the status of HV load 430, and eFUSE controller 425 may determine how much current to allow to flow through switching element 420 based on the status information. In some embodiments, HV load 430 may send a signal to eFUSE controller 425 giving permission (i.e., approval) for EIS stimulus to be applied. For example, HV load 430 may react to sensors in the car as well as operator requests for heating and cooling, and as a result, HV load 430 may know how much power is needed for its own operation.

For the aforementioned second function (implementing EIS excitation), eFUSE controller 425 generates an EIS excitation signal at a desired frequency to drive the gate of switching element 420. In an embodiment, the EIS excitation signal is a stimulus signal at a particular frequency. In another example, the eFUSE controller 420 generates a stimulus signal which has a first frequency for a first amount of time, a second frequency for a second duration of time, a third frequency for a third duration of time, and so on. For EIS measurements, the analog front end inside the battery management system (BMS) is extended with a control unit which measures the complex current and complex voltage of battery 410 and calculates the imaginary value and the real value of the current and cell voltages of battery 410. For example, for EIS measurements, the complex current and the complex voltage of battery 410 may be measured by a control unit (e.g., control unit 325 of AFE 320 of system 300), and the imaginary value and the real value of the current and cell voltages of battery 410 may be calculated by the control unit.

In an embodiment, eFUSE controller 425 may generate EIS excitation when apparatus 400 is within an electric vehicle. For example, when the battery 410 of the electric vehicle is being charged, eFUSE controller 425 may generate EIS excitation in order to determine the characteristics of battery 410. In some cases, eFUSE controller 425 may prioritize generating EIS excitation during a fast-charging mode of battery 410. Additionally, when the electric vehicle is being driven, eFUSE controller 425 may periodically generate EIS excitation in order to determine the characteristics of battery 410 during non-charging operations. This may allow for additional information to be obtained regarding the operational state of battery 410 that is not available solely during periods of time when battery 410 is being charged. This additional information may allow for operating the battery 410 closer to its performance limits (e.g., charge and discharge limits, charging speed limits, temperature limits) than would be possible without this information. This additional information may also allow for earlier detection of certain state conditions such as thermal runaway.

Depending on the embodiment, current sensing may be performed on the low side or the high side of battery 410 and synchronized with cell voltage monitoring of battery 410 via a bus interconnect such as bus 440. In an embodiment, synchronization of frequency excitations between cell monitor 450 and eFUSE controller 425 may be sent via bus 440. Bus 440 is representative of any type of interconnect which may be employed. In an embodiment, bus 440 is an isolated serial peripheral interface (SPI), also known as isoSPI. In other embodiments, bus 440 may be implemented using other types of connections and/or communication protocols. In an embodiment, eFUSE controller 425 includes a monitoring function which will stop the EISS function if the load current exceeds a programmable threshold.

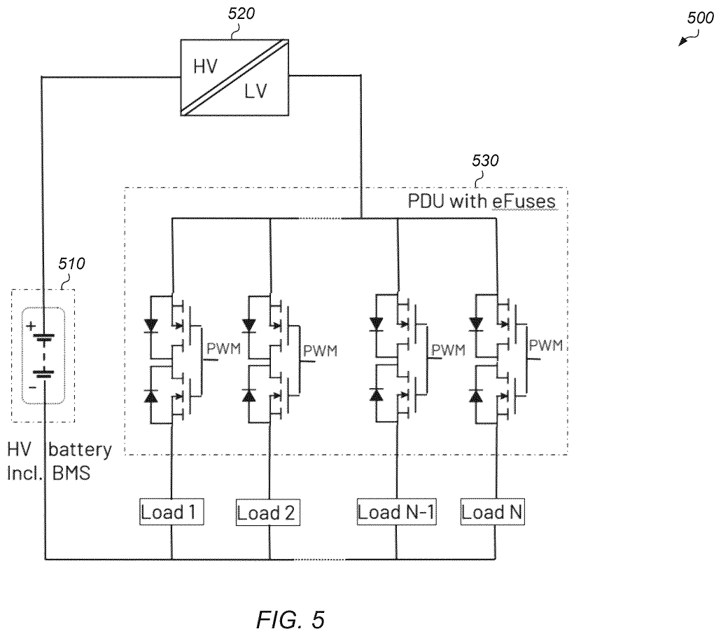

Referring now to FIG. 5, a diagram of one embodiment of a system 500 is shown, in accordance with one or more embodiments. In an embodiment, system 500 includes at least battery 510, DC-DC converter 520, power distribution unit (PDU) 530, and a plurality of loads 1-N. In an embodiment, battery 510 is a high-voltage (HV) battery, and DC-DC converter 520 may convert the voltage generated by battery 510 into a lower voltage to be coupled to PDU 530 and consumed by loads 1-N. For example, in electrified vehicles, a low voltage power network such as 48 Volts or 12 Volts is often supplied with a high voltage (e.g., 800 Volts, 400 Volts) to low voltage isolated DC/DC power supply. The number “N” of loads powered by battery 510, where “N” is a positive integer, may vary from embodiment to embodiment. Additionally, the number of switching elements contained in PDU 530 may also vary according to the implementation. In an embodiment, PDU 530 may include a separate switching element for each load of system 500.

In one embodiment, DC-DC converter 520 can be placed into a path-through mode during EIS excitation to allow the stimulus excitation frequencies to be coupled back to battery 510. In other words, when DC-DC converter 520 is in path-through mode, DC-DC converter 520 is prevented from filtering out the stimulus excitation frequencies. It is noted that path-through mode for DC-DC converter 520 may also be referred to as pass-through mode, EISS mode, or EIS mode for DC-DC converter 520. The path-through mode allows a control unit to drive PWM signals to the switching elements within PDU 530 to cause EIS stimulus to be implemented and for monitoring of battery 510 to be synchronized with the EIS stimulus. Depending on the embodiment, path-through may be a special mode, or path-through may be mode independent, in which case path-through may be achieved by designing DC-DC converter 520 to never filter the frequencies of interest for EIS stimulus.

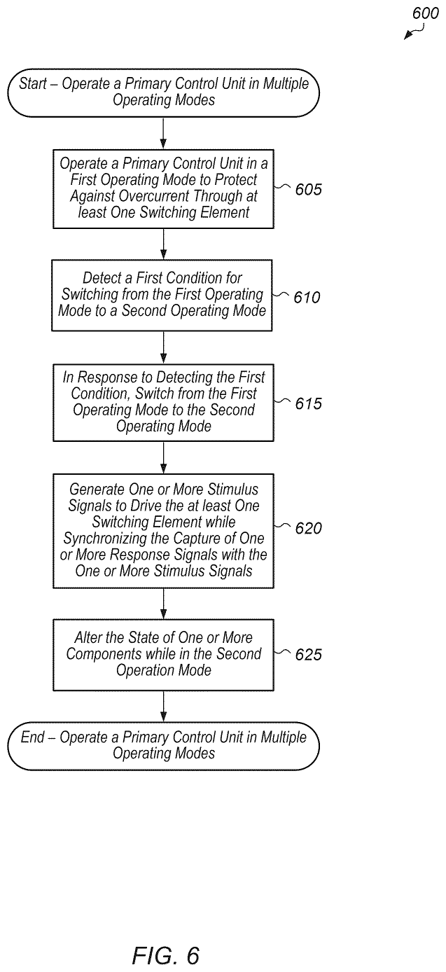

Turning now to FIG. 6, one embodiment of a method for operating a primary control unit in multiple operating modes is shown. The components embodied in any of the apparatuses or systems previously described above may generally operate in accordance with method 600. In addition, the steps in this embodiment are shown in sequential order. However, some steps may occur in a different order than shown, some steps may be performed concurrently, some steps may be combined with other steps, other steps may be added, and some steps may be absent in another embodiment.

A primary control unit (e.g., primary eFUSE controller 110 of FIG. 1) operates in a first operating mode to protect against overcurrent through at least one switching element (e.g., switching element 125A) (block 605). Next, the primary control unit detects a first condition for switching from the first operating mode to a second operating mode (block 610). In an embodiment, the first condition is a timer elapsing, with the length of time causing the timer to elapse varying from implementation to implementation. In another embodiment, the first condition is an amount of current flowing through one or more components falling below a given value. In a further embodiment, the first condition is the detection of a request from a user to switch operating modes. In other embodiments, other conditions for switching from the first operating mode to the second operating mode may be employed.

In response to detecting the first condition, the primary control unit switches from the first operating mode to the second operating mode (block 615). Then, in the second operating mode, the primary control unit generates one or more stimulus signals to drive the at least one switching element, while also synchronizing the capture of one or more response signals with the one or more stimulus signals (block 620). In an embodiment, the one or more response signals may include the imaginary values and real values of the current and cell voltages of a battery. In other embodiments, other numbers and types of response signals may be captured in synchronization with the generation of the one or more stimulus signals used to drive the at least one switching element. It is noted that the one or more response signals may be measured and analyzed to enable more efficient management of one or more associated components (e.g., a battery module). For example, in one embodiment, method 600 may be implemented to apply stimulus to a battery module while simultaneously and synchronously recording signals from the battery module using monitoring electronics attached to the battery module. Then, in this embodiment, one or more electrochemical parameters, electro-mechanical parameters, or electrical parameters of the battery module may be calculated based on the recorded signals, and a state of charge, a state of function, and a state of health of the battery module may be determined based on these parameters. These parameters may give an improved battery state accuracy for operation of the battery module as the battery module ages. Additionally, one or more recommendations may be generated based on the state of the battery module determined based on the parameters that are calculated based on the recorded signals.

While in the second operating mode, the primary control unit alters the state of one or more components (block 625). For example, in one embodiment, a DC-DC converter may be switched from a standard mode into a path-through mode to pass through the unfiltered EIS excitation signals to the battery. In an example, during path-through mode, the frequencies that are used to clock the DC-DC converter to perform the voltage conversion may be changed from a relatively low set of frequencies to a relatively high set of frequencies in order to prevent the EIS excitation signals from being filtered out. In one embodiment, the EIS excitation signals are in a range of a few Hertz (Hz) up to 5 kHz. In other embodiments, other components may be altered in order to enable EIS stimulus signals to be generated and response signals to be captured. After block 625, method 600 may end.

In an embodiment, a display unit may be employed to generate a graphical user interface to manage the operation of the battery module. The display unit may display information (e.g., one or more electrochemical parameters) regarding the battery module that is acquired by monitoring the battery module while stimulus is applied to the battery module. The information regarding the battery module that is displayed in the graphical user interface (GUI) on the display unit may include, but is not limited to, an indication of battery degradation, a quality grade of the battery module, a characteristic of the health of the battery module, and a recommendation detailing one or more actions to take during operation of the battery module. One or more input/output (I/O) devices may be employed to provide user inputs to an apparatus or system in response to the information regarding the battery module that is displayed in the GUI on the display unit. It is noted that other ways of implementing method 600 are possible and are contemplated.

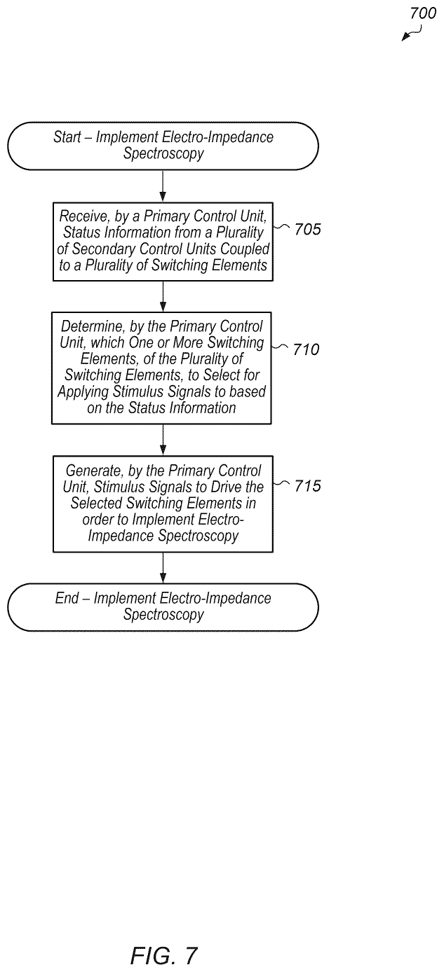

Referring now to FIG. 7, one embodiment of a method for implementing electro-impedance spectroscopy is shown. The components embodied in any of the apparatuses or systems previously described above may generally operate in accordance with method 700. In addition, the steps in this embodiment are shown in sequential order. However, some steps may occur in a different order than shown, some steps may be performed concurrently, some steps may be combined with other steps, other steps may be added, and some steps may be absent in another embodiment.

A primary control unit (e.g., primary eFUSE controller 110 of FIG. 1) receives status information from a plurality of secondary control units (e.g., secondary eFUSE controllers 120A-B) coupled to a plurality of switching elements (e.g., switching elements 125A-B) (block 705). In other words, each secondary control unit is coupled to a corresponding switching element. For example, a first secondary control unit is coupled to a first switching element, a second secondary control unit is coupled to a second switching element, a third secondary control unit is coupled to a third switching element, and so on. In one embodiment, each secondary control unit sends its present status to the primary control unit, such as whether the corresponding switching element is open or closed. This status may be updated on a periodic basis, with the frequency of updates varying from embodiment to embodiment. In another embodiment, each secondary control unit includes a current sensing mechanism to measure the current flowing through the corresponding switching element as well as through the corresponding load. The measured current may be sent from each secondary control unit to the primary control unit in this embodiment. Additional status information may also be sent from the secondary control units to the primary control unit.

Next, the primary control unit determines which one or more switching elements of the plurality of switching elements to select for applying stimulus signals (e.g., elecro-impedance spectroscopy stimulus signals) to based on the status information (block 710). In one embodiment, the primary control unit selects switching elements which are supplying a given amount of current to a load where the given amount is within a desired range of current. In another embodiment, the primary control unit selects switching elements which are supplying a given amount of current to a load where the given amount is less than a first threshold. For example, the given amount of current may only be a fraction of the maximum amount of current required for the load.

In a further embodiment, the primary control unit determines the types of loads being powered by the switching elements, and based on the types of loads, the primary control unit selects switching elements which are supplying loads which are not sensitive to PWM switching. For example, headlights on a car would be sensitive to PWM switching, resulting in modulated frequencies visible to humans, and so the primary control unit would not select the switching element which is providing current to the headlights. On the other hand, heated seats would be insensitive to the modulated frequencies, and so a particular switching element coupled to heated seats could possibly be selected by the primary control unit. In other embodiments, other criteria may be employed for determining which switching elements to select to be driven by the stimulus signals. After block 710, the primary control unit generates stimulus signals to drive the selected switching elements in order to implement electro-impedance spectroscopy (EIS) (block 715). After block 715, method 700 may end.

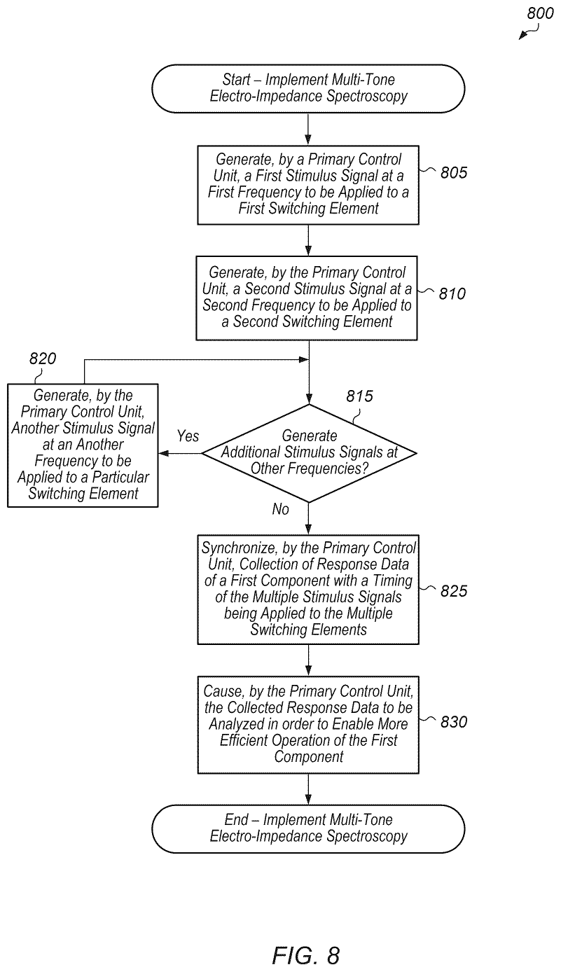

Turning now to FIG. 8, one embodiment of a method for implementing multi-tone electro-impedance spectroscopy (EIS) is shown. The components embodied in any of the apparatuses or systems previously described above may generally operate in accordance with method 800. In addition, the steps in this embodiment are shown in sequential order. However, some steps may occur in a different order than shown, some steps may be performed concurrently, some steps may be combined with other steps, other steps may be added, and some steps may be absent in another embodiment.

A primary control unit (e.g., primary eFUSE controller 110 of FIG. 1) generates a first stimulus signal at a first frequency to be applied to a first switching element (e.g., switching element 125A) (block 805). In other words, the primary control unit causes a gate of the first switching element to be driven with a first stimulus signal (e.g., a PWM signal) at a first frequency. Also, the primary control unit generates a second stimulus signal at a second frequency to be applied to a second switching element (e.g., switching element 125B) (block 810). It is assumed for the purposes of this discussion that the second frequency is different from the first frequency. Next, the primary control unit determines whether to generate additional stimulus signals at other frequencies (conditional block 815). If the primary control unit determines to generate an additional stimulus signal at a frequency different from the first and second frequencies (conditional block 815, “yes” leg), then the primary control unit generates another stimulus signal at another frequency to be applied to a particular switching element (block 820). Otherwise, if the primary control unit determines that additional stimulus signals at other frequencies should not be generated (conditional block 815, “no” leg), then the primary control unit synchronizes the collection of response data of a first component (e.g., a battery module) with a timing of the multiple stimulus signals being applied to the multiple switching elements (block 825). Then, the primary control unit causes the collected response data to be analyzed in order to enable more efficient operation of the first component (block 830). In an example, multiple stimulus signals are generated and applied to multiple switching elements while response data is collected from a battery module while the battery module is being charged. In another example, multiple stimulus signals are generated and applied to multiple switching elements while response data is collected from a battery module which is powering one or more loads. After block 830, method 800 may end.

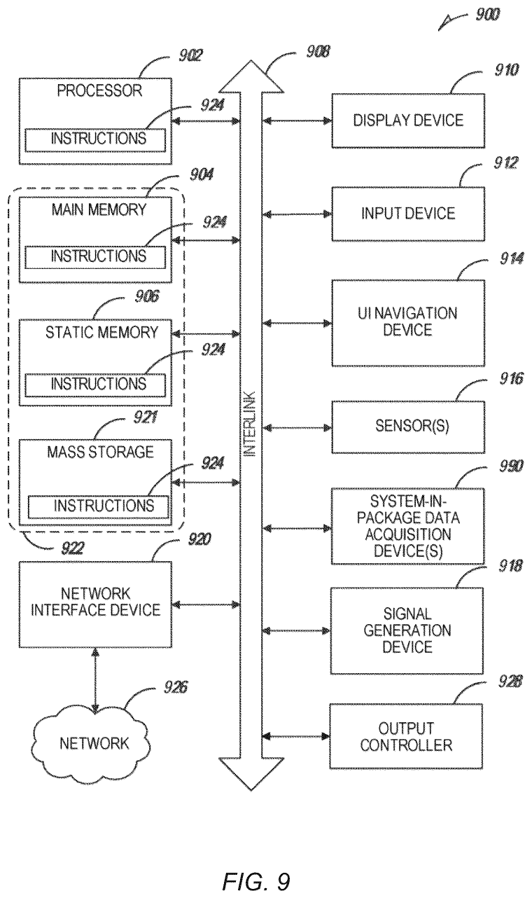

Referring now to FIG. 9, a block diagram of an example machine 900 upon which any one or more of the techniques (e.g., methodologies) discussed herein may be performed is shown. In various embodiments, the machine 900 may operate as a standalone device or may be connected (e.g., networked) to other machines which may include at least a portion of the circuitry shown in FIGS. 1-5. Alternatively and/or additionally, the machine 900 may include at least a portion of the circuitry shown in FIGS. 1-5. While the machine 900 is shown as including a plurality of components in FIG. 9, it should be understood that this is merely indicative of one embodiment. In other embodiments, one or more of the components shown in FIG. 9 may be omitted from the machine 900. Additionally, in further embodiments, one or more components not shown in FIG. 9 may be included in the machine 900.

In a networked deployment, the machine 900 may operate in the capacity of a server machine, a client machine, or both in server-client network environments. In an example, the machine 900 may act as a peer machine in a peer-to-peer (P2P) (or other distributed) network environment. The machine 900 may be a computer system, a personal computer (PC), a tablet PC, a set-top box (STB), a personal digital assistant (PDA), a mobile telephone, a web appliance, an IoT device, an automotive system, an aerospace system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic). Circuitry membership may be flexible over time and underlying hardware variability. Circuitries include members that may, alone or in combination, perform specific tasks. In an example, hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by moveable placement of invariant-massed particles) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuit. For example, under operation, execution units may be used in a first circuit of first circuitry at one point in time and reused by a second circuit in the first circuitry, or by a third circuit in second circuitry, at a different time.

The machine 900 may include a hardware processor 902 (e.g., a central processing unit (CPU), a graphics processing unit (GPU)), a main memory 904, and a static memory 906, some or all of which may communicate with each other via an interlink 908. Interlink 908 may also be referred to as a bus. The machine 900 may further include a display device 910, an alphanumeric input device 912 (e.g., a keyboard), and a user interface (UI) navigation device 914 (e.g., a mouse). In an example, the display device 910, alphanumeric input device 912, and UI navigation device 914 may be touchscreen displays. The machine 900 may additionally include a storage device 922 (e.g., drive unit); a signal generation device 918 (e.g., a speaker); a network interface device 920; one or more sensors 916, such as a Global Positioning System (GPS) sensor, wing sensor, mechanical device sensor, temperature sensor, bridge sensor, audio sensor, industrial sensor, a compass, an accelerometer, or other sensors; and one or more system-in-package data acquisition devices 990. The machine 900 may include an output controller 928, such as a serial (e.g., universal serial bus (USB)), parallel, or other wired or wireless (e.g., infrared (IR), near field communication (NFC)) connection to communicate with or control one or more peripheral devices (e.g., a printer, card reader).

The storage device 922 may include a machine-readable storage medium on which is stored one or more sets of data structures or instructions 924 (e.g., software) embodying or utilized by any one or more of the techniques or functions described herein. The instructions 924 may also reside, completely or at least partially, within the main memory 904, within the static memory 906, or within the hardware processor 902 during execution thereof by the machine 900. In an example, one or any combination of the hardware processor 902, the main memory 904, the static memory 906, or the storage device 922 may constitute the machine-readable storage medium. While the machine-readable storage medium is illustrated as a single medium, the term “machine-readable storage medium” may include a single medium or multiple media (e.g., a centralized or distributed database, or associated caches and servers) configured to store the one or more instructions 924.

The term “machine-readable storage medium” may include any transitory or non-transitory medium that is capable of storing, encoding, or carrying transitory or non-transitory instructions for execution by the machine 900 and that cause the machine 900 to perform any one or more of the techniques of the present disclosure, or that is capable of storing, encoding, or carrying data structures used by or associated with such instructions. Non-limiting machine-readable storage medium examples may include solid-state memories and optical and magnetic media. In an example, a massed machine-readable storage medium comprises a machine-readable medium with a plurality of particles having invariant (e.g., rest) mass. Accordingly, massed machine-readable storage media are not transitory propagating signals. Specific examples of massed machine-readable storage media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 924 (e.g., software, programs, an operating system (OS)) or other data that are stored on the storage device 921 may be accessible via main memory 904 for use by the hardware processor 902. The main memory 904 (e.g., DRAM) is typically fast, but volatile, and thus a different type of storage from the storage device 921 (e.g., an SSD), which is suitable for long-term storage, including while in an “off” condition. The instructions 924 or data in use by a user or the machine 900 are typically loaded in the main memory 904 for use by the hardware processor 902. When the main memory 904 is full, virtual space from the storage device 921 can be allocated to supplement the main memory 904. However, because the storage device 921 is typically slower than the main memory 904, and write speeds are typically at least twice as slow as read speeds, use of virtual memory can greatly reduce user experience due to storage device latency (in contrast to the main memory 904). Further, use of the storage device 921 for virtual memory can greatly reduce the usable lifespan of the storage device 921.

The instructions 924 may further be transmitted or received over a communications network 926 using a transmission medium via the network interface device 920 utilizing any one of a number of transfer protocols (e.g., frame relay, internet protocol (IP), transmission control protocol (TCP), user datagram protocol (UDP), hypertext transfer protocol (HTTP)). Example communication networks may include a local area network (LAN), a wide area network (WAN), a packet data network (e.g., the Internet), mobile telephone networks (e.g., cellular networks), Plain Old Telephone Service (POTS) networks, and wireless data networks (e.g., Institute of Electrical and Electronics Engineers (IEEE) 802.11 family of standards known as Wi-Fi®, IEEE 802.16 family of standards known as WiMax®, IEEE 802.15.4 family of standards, P2P networks), among others. In an example, the network interface device 920 may include one or more physical jacks (e.g., Ethernet, coaxial, or phone jacks) or one or more antennas to connect to the communications network 926. In an example, the network interface device 920 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible or intangible medium that is capable of storing, encoding, or carrying instructions for execution by the machine 900, and includes digital or analog communications signals or other tangible or intangible media to facilitate communication of such software.

The following are example embodiments of systems, apparatuses, and methods of operation, in accordance with the teachings herein:

Example 1 includes subject matter such as a system comprising at least one switching element; and a primary control unit configured to: operate in a first operating mode to monitor an amount of current passing through the at least one switching element to protect against an overcurrent event by opening a current path in response to detecting an overcurrent event; operate in a second operating mode to: generate one or more stimulus signals to drive the at least one switching element; and capture one or more response signals in response to the one or more stimulus signals.

In Example 2, the subject matter of Example 1 optionally includes having the one or more stimulus signals comprise a first stimulus signal at a first frequency and a second stimulus signal at a second frequency, wherein the second frequency is different from the first frequency.

In Example 3, the subject matter of one or both of Examples 1 and 2 optionally includes the primary control unit being further configured to cause a power converter to enter a path-through mode in response to the primary control unit operating in the second operating mode.

In Example 4, the subject matter of one or any combination of Examples 1-3 optionally includes the one or more stimulus signals being electro-impedance spectroscopy excitation signals, and wherein the at least one switching element is an electronic fuse.

In Example 5, the subject matter of one or any combination of Examples 1-4 optionally includes at least one secondary control unit configured to: receive control signals from the primary control unit; and convey status information, corresponding to the at least one switching element, to the primary control unit.

In Example 6, the subject matter of one or any combination of Examples 1-5 optionally includes the primary control unit being further configured to select a given switching element from a plurality of switching elements for applying the one or more stimulus signals, wherein the selection of the given switching element is based at least on the status information conveyed to the primary control unit from the secondary control unit.

In Example 7, the subject matter of one or any combination of Examples 1-6 optionally includes a battery, wherein the primary control unit is configured to synchronize monitoring of the battery during the generation of the one or more stimulus signals so as to capture the one or more response signals from the battery.

In Example 8, the subject matter of one or any combination of Examples 1-7 optionally includes the primary control unit being further configured to convey one or more synchronization signals to the battery so as to capture the one or more response signals based on a timing of the generation of one or more stimulus signals.

Example 9 includes subject matter such as an apparatus configured to: operate in a first operating mode to protect against overcurrent through at least one switching element by opening a current path of the at least one switching element; operate in a second operating mode to: generate one or more stimulus signals to drive the at least one switching element; and capture one or more response signals in response to the one or more stimulus signals.

In Example 10, the subject matter of Example 9 optionally includes the one or more stimulus signals comprising a first stimulus signal at a first frequency and a second stimulus signal at a second frequency, wherein the second frequency is different from the first frequency.

In Example 11, the subject matter of one or both of Examples 9 and 10 optionally includes the apparatus being further configured to cause a power converter to enter path-through mode while operating in the second operating mode.

In Example 12, the subject matter of one or any combination of Examples 9-11 optionally includes that the one or more stimulus signals are electro-impedance spectroscopy excitation signals, and wherein the at least one switching element is an electronic fuse.

In Example 13, the subject matter of one or any combination of Examples 9-12 optionally includes the apparatus being further configured to receive status information corresponding to the at least one switching element.

In Example 14, the subject matter of one or any combination of Examples 9-13 optionally includes the apparatus being further configured to select a given switching element from a plurality of switching elements for applying the one or more stimulus signals, wherein the selection of the given switching element is based at least on the received status information.

In Example 15, the subject matter of one or any combination of Examples 9-14 optionally includes the apparatus being further configured to synchronize monitoring of a battery during the generation of the one or more stimulus signals so as to capture the one or more response signals from the battery.

In Example 16, the subject matter of one or any combination of Examples 9-15 optionally includes the apparatus is further configured to convey one or more synchronization signals to the battery so as to capture the one or more response signals based on a timing of the generation of one or more stimulus signals.

Example 17 includes subject matter such as a method comprising: operating a control unit in a first mode in response to detecting a first condition, wherein when operating in the first mode, the control unit is configured to control an electronic fuse with one or more control signals; and operating the control unit in a second mode in response to detecting a second condition, wherein when operating in the second mode, the control unit is configured to generate at least one electrochemical impedance spectroscopy signal to make at least one impedance measurement.

In Example 18, the subject matter of Example 17 optionally includes that the first condition is an over-current event, and wherein the second condition is a first load being supplied with less than a threshold amount of current.

In Example 19, the subject matter of one or both of Examples 17 and 18 optionally includes the method further comprising performing at least one action in response to the at least one impedance measurement.

In Example 20, the subject matter of one or any combination of Examples 17-19 optionally includes the method further comprising performing at least one action in response to at least one comparison of the at least one impedance measurement to at least one threshold value

The systems and methods disclosed herein can be embodied in various forms including, for example, a data processor, such as a computer that also includes a database, digital electronic circuitry, firmware, software, or in combinations of them. Moreover, the above-noted features and other aspects and principles of the present disclosed implementations can be implemented in various environments. Such environments and related applications can be specially constructed for performing the various processes and operations according to the disclosed implementations or they can include a general-purpose computer or computing platform selectively activated or reconfigured by code to provide the necessary functionality. The processes disclosed herein are not inherently related to any particular computer, network, architecture, environment, or other apparatus, and can be implemented by a suitable combination of hardware, software, and/or firmware. For example, various general-purpose machines can be used with programs written in accordance with teachings of the disclosed implementations, or it can be more convenient to construct a specialized apparatus or system to perform the required methods and techniques.

Although ordinal numbers such as first, second and the like can, in some situations, relate to an order; as used in a document ordinal numbers do not necessarily imply an order. For example, ordinal numbers can be merely used to distinguish one item from another. For example, to distinguish a first event from a second event, but need not imply any chronological ordering or a fixed reference system (such that a first event in one paragraph of the description can be different from a first event in another paragraph of the description.

It is noted that the above-described embodiments may comprise software and/or computer programs. These computer programs, which can also be referred to programs, software, software applications, applications, components, or code, include program instructions (i.e., machine instructions) for a programmable processor, and can be implemented in a high-level procedural and/or object-oriented programming language, and/or in assembly/machine language. As used herein, the term “machine-readable storage medium” refers to any computer program product, apparatus and/or device, such as for example magnetic discs, optical disks, memory, and Programmable Logic Devices (PLDs), used to provide machine instructions and/or data to a programmable processor, including a machine-readable storage medium that receives program instructions as a machine-readable signal. The term “machine-readable signal” refers to any signal used to provide machine instructions and/or data to a programmable processor. The machine-readable storage medium can store such program instructions non-transitorily, such as for example would a non-transient solid-state memory or a magnetic hard drive or any equivalent storage medium. The machine-readable storage medium can alternatively or additionally store such machine instructions in a transient manner, such as would a processor cache or other random-access memory associated with one or more physical processor cores.

In various embodiments, the program instructions that implement the methods and/or mechanisms may be conveyed or stored on a non-transitory computer readable storage medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage.

Non-transitory computer program products (i.e., physically embodied computer program products) are also described that store instructions, which when executed by one or more data processors of one or more computing systems, causes at least one data processor to perform operations herein. Similarly, computer systems are also described that may include one or more data processors and memory coupled to the one or more data processors. The memory may temporarily or permanently store instructions that cause at least one processor to perform one or more of the operations described herein. In addition, methods can be implemented by one or more data processors either within a single computing system or distributed among two or more computing systems. Such computing systems can be connected and can exchange data and/or commands or other instructions or the like via one or more connections, including a connection over a network (e.g., the Internet, a wireless wide area network, a local area network, a wide area network, a wired network, or the like), via a direct connection between one or more of the multiple computing systems, etc.

To provide for interaction with a user, the subject matter described herein can be implemented on a computer having a display device, such as for example a cathode ray tube (CRT) or a liquid crystal display (LCD) monitor for displaying information to the user and a keyboard and a pointing device, such as for example a mouse or a trackball, by which the user can provide input to the computer. Other kinds of devices can be used to provide for interaction with a user as well. For example, feedback provided to the user can be any form of sensory feedback, such as for example visual feedback, auditory feedback, or tactile feedback; and input from the user can be received in any form, including acoustic, speech, or tactile input.

The subject matter described herein can be implemented in a computing system that includes a back-end component, such as for example one or more data servers, or that includes a middleware component, such as for example one or more application servers, or that includes a front-end component, such as for example one or more client computers having a graphical user interface or a web browser through which a user can interact with an implementation of the subject matter described herein, or any combination of such back-end, middleware, or front-end components. The components of the system can be interconnected by any form or medium of digital data communication, such as for example a communication network. Examples of communication networks include, but are not limited to, a local area network (“LAN”), a wide area network (“WAN”), and the Internet.

A computing system may include clients and servers. A client and server are generally, but not exclusively, remote from each other and typically interact through a communication network. The relationship of client and server arises by virtue of computer programs running on the respective computers and having a client-server relationship to each other.

In various embodiments, one or more portions of the methods and mechanisms described herein may form part of a cloud-computing environment. In such embodiments, resources may be provided over the Internet as services according to one or more various models. Such models may include Infrastructure as a Service (IaaS), Platform as a Service (PaaS), and Software as a Service (SaaS). In IaaS, computer infrastructure is delivered as a service. In such a case, the computing equipment is generally owned and operated by the service provider. In the PaaS model, software tools and underlying equipment used by developers to develop software solutions may be provided as a service and hosted by the service provider. SaaS typically includes a service provider licensing software as a service on demand. The service provider may host the software, or may deploy the software to a customer for a given period of time. Numerous combinations of the above models are possible and are contemplated.

The present disclosure includes references to an “embodiment”, to one “embodiment”, or to groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be achieved, but rather to recognize that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” or is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “clamping unit” may be described as performing the function of “clamp an output of an amplifier,” which means that the clamping unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g. passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. § 112(f) for that unit/circuit/component.

The Abstract is provided to comply with 37 C.F.R. § 1.72(b), to allow the reader to quickly ascertain the nature of the technical disclosure. It is submitted with the understanding that it will not be used to interpret or limit the scope or meaning of the claims.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A system comprising:
at least one switching element; and
a primary control unit configured to:
operate in a first operating mode to monitor an amount of current passing through the at least one switching element to protect against an overcurrent event by opening a current path in response to detecting an overcurrent event;
operate in a second operating mode to:
generate one or more stimulus signals to drive the at least one switching element; and
capture one or more response signals in response to the one or more stimulus signals.

2. The system of claim 1, wherein the one or more stimulus signals comprises a first stimulus signal at a first frequency and a second stimulus signal at a second frequency, wherein the second frequency is different from the first frequency.

3. The system of claim 1, wherein the primary control unit is further configured to cause a power converter to enter a path-through mode in response to the primary control unit operating in the second operating mode.

4. The system of claim 1, wherein the one or more stimulus signals are electro-impedance spectroscopy excitation signals, and wherein the at least one switching element is an electronic fuse.

5. The system of claim 1, further comprising at least one secondary control unit configured to:
receive control signals from the primary control unit; and
convey status information, corresponding to the at least one switching element, to the primary control unit.

6. The system of claim 5, wherein the primary control unit is further configured to select a given switching element from a plurality of switching elements for applying the one or more stimulus signals, wherein the selection of the given switching element is based at least on the status information conveyed to the primary control unit from the secondary control unit.

7. The system of claim 1, further comprising a battery, wherein the primary control unit is configured to synchronize monitoring of the battery during the generation of the one or more stimulus signals so as to capture the one or more response signals from the battery.

8. The system of claim 7, wherein the primary control unit is further configured to convey one or more synchronization signals to the battery so as to capture the one or more response signals based on a timing of the generation of one or more stimulus signals.

9. An apparatus configured to:
operate in a first operating mode to protect against overcurrent through at least one switching element by opening a current path of the at least one switching element;
operate in a second operating mode to:
generate one or more stimulus signals to drive the at least one switching element; and
capture one or more response signals in response to the one or more stimulus signals.

10. The apparatus of claim 9, wherein the one or more stimulus signals comprises a first stimulus signal at a first frequency and a second stimulus signal at a second frequency, wherein the second frequency is different from the first frequency.

11. The apparatus of claim 9, wherein the apparatus is further configured to cause a power converter to enter path-through mode while operating in the second operating mode.

12. The apparatus of claim 11, wherein the one or more stimulus signals are electro-impedance spectroscopy excitation signals, and wherein the at least one switching element is an electronic fuse.

13. The apparatus of claim 9, wherein the apparatus is further configured to receive status information corresponding to the at least one switching element.

14. The apparatus of claim 13, wherein the apparatus is further configured to select a given switching element from a plurality of switching elements for applying the one or more stimulus signals, wherein the selection of the given switching element is based at least on the received status information.

15. The apparatus of claim 9, wherein the apparatus is further configured to synchronize monitoring of a battery during the generation of the one or more stimulus signals so as to capture the one or more response signals from the battery.

16. The apparatus of claim 15, wherein the apparatus is further configured to convey one or more synchronization signals to the battery so as to capture the one or more response signals based on a timing of the generation of one or more stimulus signals.

17. A method comprising:
operating a control unit in a first mode in response to detecting a first condition, wherein when operating in the first mode, the control unit is configured to control an electronic fuse with one or more control signals; and
operating the control unit in a second mode in response to detecting a second condition, wherein when operating in the second mode, the control unit is configured to generate at least one electrochemical impedance spectroscopy signal to make at least one impedance measurement.

18. The method of claim 17, wherein the first condition is an over-current event, and wherein the second condition is a first load being supplied with less than a threshold amount of current.

19. The method of claim 17, further comprising performing at least one action in response to the at least one impedance measurement.

20. The method of claim 17, further comprising performing at least one action in response to at least one comparison of the at least one impedance measurement to at least one threshold value.
